(19) United States
(12) Patent Application Publication
(10) Pub. No.: US 2013/0078556 A1
(43) Pub. Date: Mar. 28, 2013

(54) COLOR RESIN COMPOSITION AND METHOD FOR FORMING MULTICOLOR COLOR FILTERS

(71) Applicants: Feng-Chin Tang, Taoyuan County (TW); Wen-Jen Hsieh, Taoyuan County (TW); Ying-Hung Chuang, Taoyuan County (TW)

(72) Inventors: Feng-Chin Tang, Taoyuan County (TW); Wen-Jen Hsieh, Taoyuan County (TW); Ying-Hung Chuang, Taoyuan County (TW)

(21) Appl. No.: 13/407,733

(22) Filed: Feb. 28, 2012

(30) Foreign Application Priority Data
Sep. 23, 2011 (TW) 100134416

(51) Int. Cl. G03F 7/20; C08L 33/10; B05D 5/06; C08K 5/101; C08K 5/07; G03F 7/028; C08K 5/3445

(52) U.S. Cl. 430/7; 430/281.1; 430/285.1; 522/107; 522/75; 522/79; 427/162

(57) ABSTRACT

A method for forming multicolor color filters is disclosed. First, a first patterned color layer is formed on a substrate. Second, a second patterned color layer and a third patterned color layer are respectively formed on the substrate with the first patterned color layer. Then the first patterned color layer, the second patterned color layer and the third patterned color layer are baked together to simultaneously transform the first patterned color layer, the second patterned color layer and the third patterned color layer to respectively become a first pixel color layer, a second pixel color layer and a third pixel color layer of the multicolor color filters, respectively.

### BACKGROUND OF THE INVENTION

1. Field of the Invention

The present invention generally relates to a color resin composition and to a method of using the color resin composition to form multicolor color filters. In particular, the present invention is directed to a specially formulated color resin composition and to a method of using the color resin composition to form multicolor color filters by merely one single baking step.

2. Description of the Prior Art

A color filter is one of the critical components of a color display and the cost of the color filter is a relatively high factor of the total production cost of the color display. The function of the color filters is to display color images by adjusting the light form a light source of the backlight.

The conventional procedures for fabricating the color filters may be as follows. First, organic materials of different colors, such as red, green and blue, are formed in each pixel by lithographic and, exposure steps. After each lithographic or exposure step, a cleaning and brushing step is required to be done on the organic materials. However, peel-off or defects are often observed because organic materials of different colors are not robust enough to endure the damages of the cleaning step or brushing step after the organic materials of different colors undergo the lithographic or exposure steps. As a result, a thermal curing step must be introduced to bake the organic materials so as to make sure that the cleaning and brushing step are not going to do any damages on the developed organic materials, that is, the product at this stage—the color filters, after the lithographic or exposure steps but before the cleaning and brushing step.

Although the baking step may strengthen the robustness of the organic materials and ensures that the cleaning and brushing step may not collaterally damage the developed organic materials, some collateral problems still happen. For example, the organic materials finished at the first baking step must undergo two more baking steps than the organic materials finished at the third baking step. As far as the organic materials finished at the first baking step are concerned, the two additional baking steps, i.e. the two later baking steps, are not only totally unnecessary but are also energy-wasting. In such a way, each baking step in one aspect increases the thermal budget and in another aspect may potentially once more alter the chemical or the physical properties of the organic materials.

Given the above, a novel method for making multicolor color filters is still needed to improve the current fabricating process to further cut the thermal budget.

### SUMMARY OF THE INVENTION

In the light of this, the present invention proposes a novel method for forming multicolor color filters. The novel method for forming multicolor color filters of the present invention not only omits unnecessary baking steps but also makes the multicolor color filters fabricated by the present invention not substantially distinct from those fabricated by a conventional process. In addition, the ordinary and necessary cleaning and brushing steps after the lithographic or exposure steps do not substantially harm the originally formulated color filters of the present invention and do not cause any peel-off or defects. To sum up, the novel method of the present invention is indeed able to improve the current fabricating process.

The present invention in a first aspect proposes a novel method for forming multicolor color filters. First, a substrate is provided. Second, a first patterned color layer is formed on the substrate. The first patterned color layer has a first color. Then, a second patterned color layer is formed on the substrate which already has the first patterned color layer. The second patterned color layer has a second color. Next, a third patterned color layer is formed on the substrate which simultaneously has the first patterned color layer and the second patterned color layer. The third patterned color layer has a third color and the first color, the second color and the third color being mutually different. The positions of the first patterned color layer, the second patterned color layer and the third patterned color layer are respectively different. Later, the first patterned color layer, the second patterned color layer and the third patterned color layer together are simultaneously baked to turn into a first pixel color layer of the multicolor color filters, into a second pixel color layer of the multicolor color filters and into a third pixel color layer of the multicolor color filters.

In one embodiment of the present invention, at least one of a printing screen process and a spraying process is used to form the first patterned color layer, the second patterned color layer or the third patterned color layer.

In another embodiment of the present invention, the formation of the first patterned color layer may further include the following steps. First, a first color photoresist layer is formed on the substrate. Second, the first color photoresist layer is exposed and developed to form the first patterned color layer.

In another embodiment of the present invention, the present invention may further include the following step after the formation of the first patterned color layer. The first patterned color layer is washed without substantially being damaged.

In another embodiment of the present invention, the present invention may further include the following step after the formation of the first patterned color layer. The first patterned color layer is brushed without being substantially damaged.

In another embodiment of the present invention, the formation of the second patterned color layer may further include the following steps. First, a second color photoresist layer is formed on the substrate. Second, the second color photoresist layer is exposed and developed to form the second patterned color layer.

In another embodiment of the present invention, the present invention may further include the following step after the formation of the second patterned color layer. The second patterned color layer is washed without substantially being damaged.

In another embodiment of the present invention, the present invention may further include the following step after the formation of the second patterned color layer. The second patterned color layer is brushed without being substantially damaged.

In another embodiment of the present invention, the formation of the third patterned color layer may further include the following steps. First, a third color photoresist layer is formed on the substrate. Second, the third color photoresist layer is exposed and developed to form the third patterned color layer.

In another embodiment of the present invention, the present invention may further include the following step after the formation of the third patterned color layer. The third patterned color layer is washed without substantially being damaged.

In another embodiment of the present invention, the present invention may further include the following step after the formation of the third patterned color layer. The third patterned color layer is brushed without being substantially damaged.

In another embodiment of the present invention, the first patterned color layer, the second patterned color layer and the third patterned color layer are baked for around 20-40 minutes at a temperature around 200° C.-240° C.

In another embodiment of the present invention, the first color, the second color and the third color are selected from a group consisting of red, green and blue.

In another embodiment of the present invention, the first patterned color layer, the second patterned color layer and the third patterned color layer may respectively and independently include:

a hydrophobic resin of 15%-25% of a total weight;

an acrylate reactive monomer of 10%-20% of the total weight;

a photo-initiator of 0.5%-3% of the total weight; and

a solvent of 55%-75% of the total weight.

In another embodiment of the present invention, at least one of the first patterned color layer, the second patterned color layer and the third patterned color layer further includes:

an additive up to 3% of the total weight.

The present invention in a second aspect proposes a color resin composition. The color resin composition includes:

a hydrophobic resin of 15%-25% of a total weight;

an acrylate reactive monomer of 10%-20% of the total weight;

a photo-initiator of 0.5%-3% of the total weight; and

a solvent of 55%-75% of the total weight.

In one embodiment of the present invention, the hydrophobic resin is selected from the following compound:

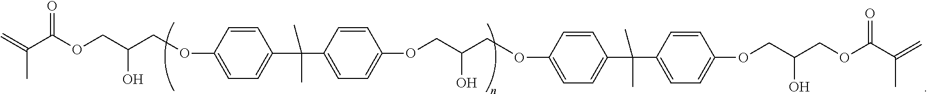

In another embodiment of the present invention, the acrylate reactive monomer includes:

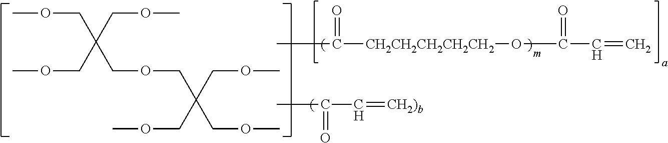

wherein a is 6 and b is 0.

In another embodiment of the present invention, the color resin composition of the present invention may further include:

an additive up to 3% of the total weight.

In another embodiment of the present invention, the additive includes a thiol compound.

In another embodiment of the present invention, the color resin composition may be red, green or blue.

In another embodiment of the present invention, the solvent may include at least one of ethyl 3-ethoxypropionate, 1-methoxy-2-propyl acetate, 3-methoxybutyl acetate and cyclohexanone.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 illustrate an embodiment for forming multicolor color filters of the present invention.

FIG. 12 illustrates a suitable hydrophobic resin of the present invention.

FIGS. 13A-13C illustrate some suitable photo-initiators of the present invention.

### DETAILED DESCRIPTION

The novel method for forming multicolor color filters of the present invention may omit unnecessary baking steps and save the thermal budget. At the same time, the multicolor color filters made by the present invention are not substantially distinct from those made by a conventional process. In addition, the color filters of the present invention have original formulation to be able to endure the ordinary and necessary cleaning and brushing steps after the lithographic or exposure steps without being substantially damaged or peeled off.

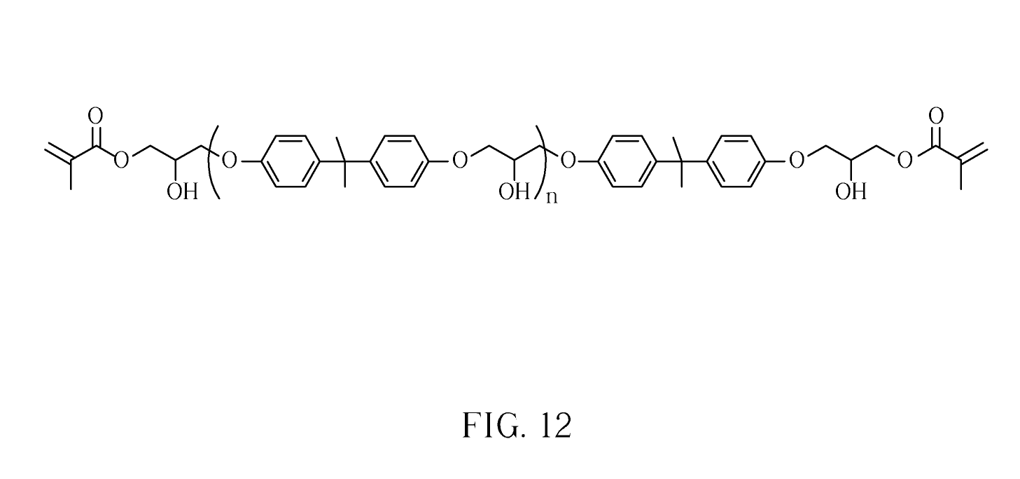

The present invention in a first aspect provides a robust color resin composition. The robust color resin composition of the present invention has a higher mechanical strength and outstanding hydrophobic property and is able to endure the direct contact and scrub of the detergent and the brushes without causing any peel-off or defects. The color resin composition of the present invention includes a hydrophobic resin, an acrylate reactive monomer, a photo-initiator and a solvent. The hydrophobic resin is usually 15%-25% of a total weight, preferably 17% of the total weight. The hydrophobic resin may have organic hydrophobic molecules. A suitable hydrophobic resin may be the compound as shown in FIG. 12.

The acrylate reactive monomer is usually 10%-20% of the total weight, preferably 16% of the total weight. The acrylate reactive monomer is usually an acrylate compound with active double-bound(s) which is capable of polymerizing. A suitable acrylate reactive monomer may be:

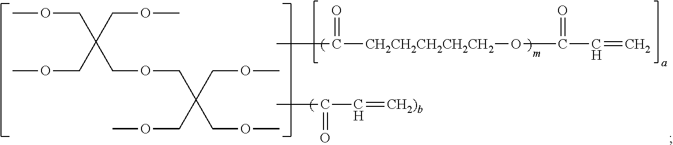

a may be 6 and b may be 0.

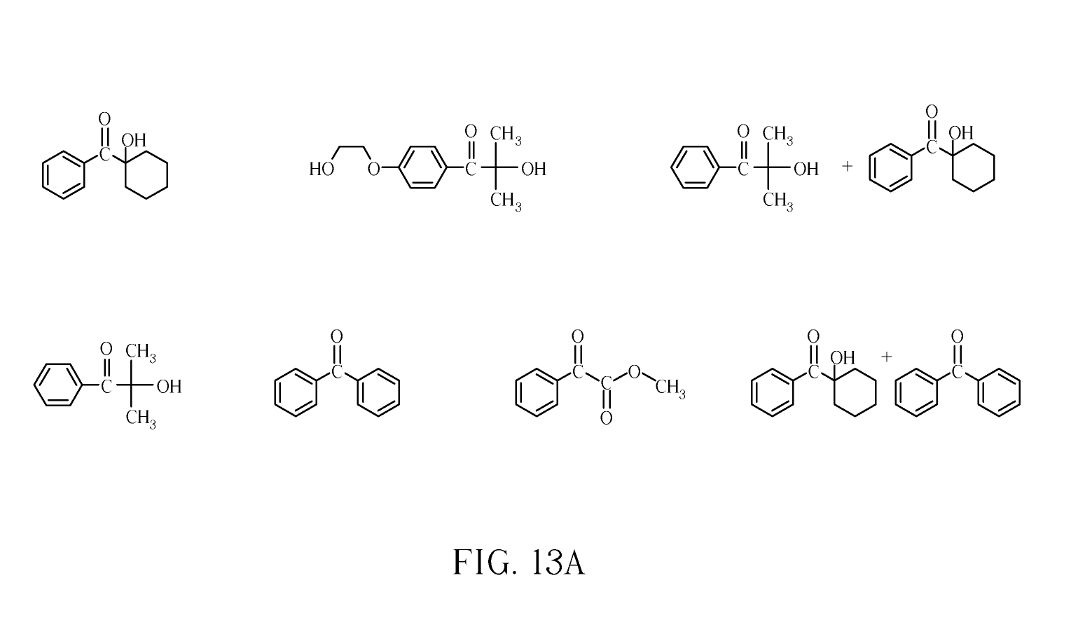

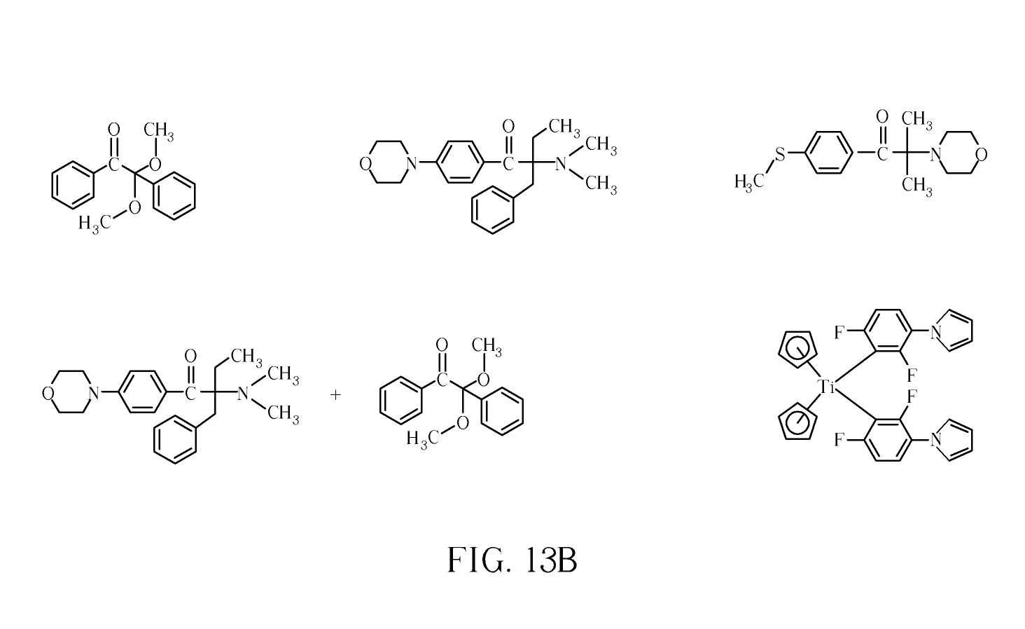

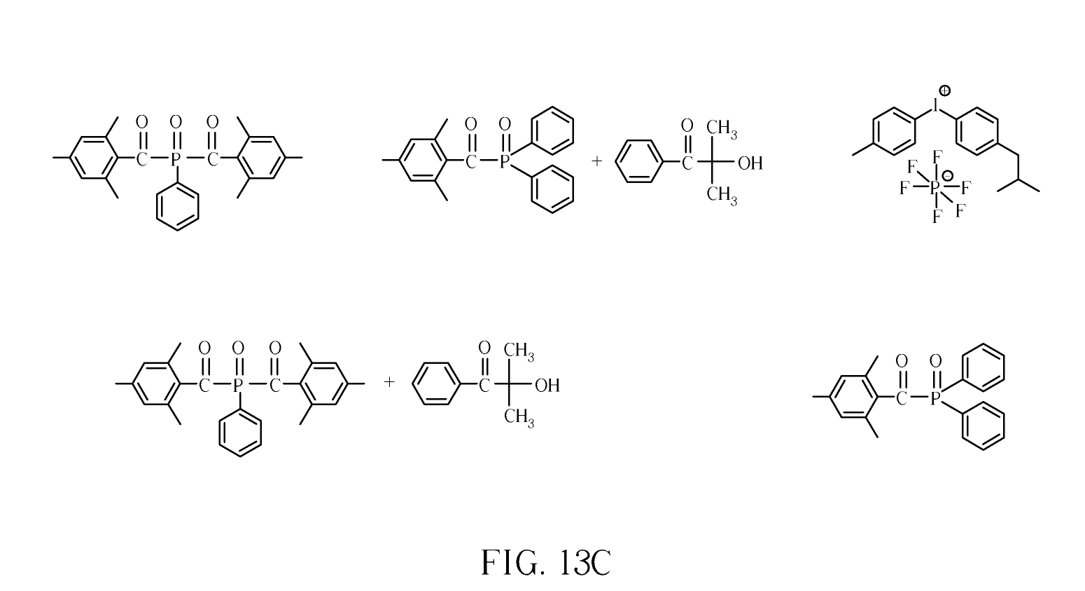

The photo-initiator is usually 0.5%-3% of the total weight, preferably 2.2% of the total weight, to initiate a photo-polymerization reaction. A better photo-initiator is sensitive. For example, it has an extraordinarily high absorption to a wavelength of 365 nm. Some suitable photo-initiators may be the compounds as shown in FIGS. 13A-13C.

The solvent usually has a larger weight percentage of the total composition. For example, the solvent may be 55%-75% of the total weight, preferably 62.8% of the total weight. The solvent is usually an inert liquid to uniformly dissolve the above ingredients. The solvent may be polyethers. A suitable polyether may be ethyl 3-ethoxypropionate, 1-methoxy-2propyl acetate, 3-methoxybutyl acetate or cyclohexanone.

In one embodiment of the present invention, the color resin composition of the present invention may optionally include an additive up to 3% of the total weight, to improve or to adjust the properties of the color resin composition of the present invention. For example, the additive may include a thiol compound of the following chemical structure (1) to enhance the photo-polymerization reaction:

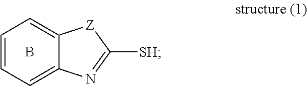

Z may be NH or S.

The color resin composition of the present invention may have any one of the colors such as red, green or blue. The color resin composition of the present invention may enhance the cross-linking of the photoresist reaction, the photoresist hydrophobic property, to avoid possible light-leaking or peeling after the development procedure. As a result, the patterned color layers of the present invention are able to have sufficient mechanical strength and hydrophobic property to endure the damages of the detergent and brushes during the washing or the brushing step so the patterned color layers (the photoresist) of the present invention do not peel off or have defects after the washing or the brushing step.

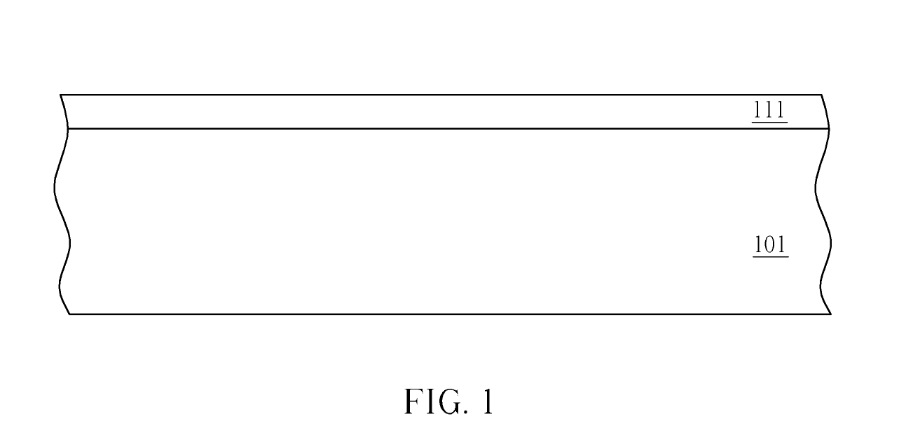

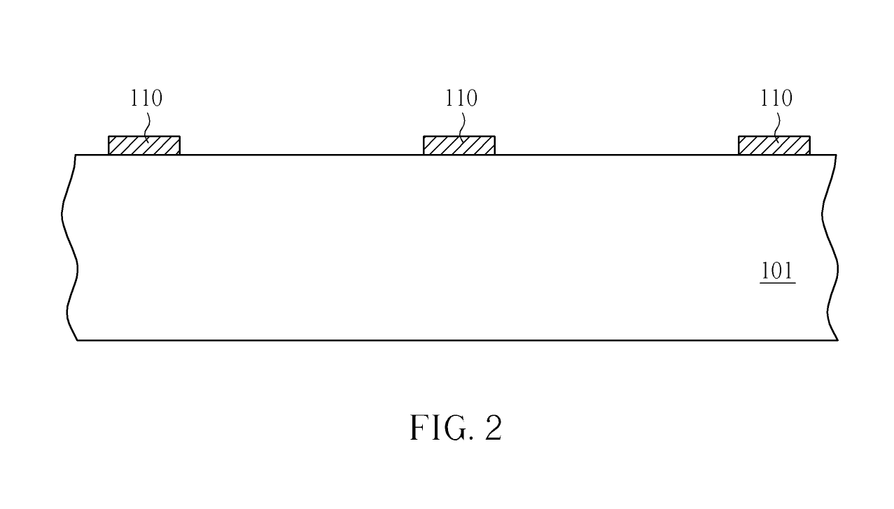

The present invention in a second aspect provides a novel method for forming multicolor color filters. FIGS. 1-11 illustrate an embodiment for forming multicolor color filters of the present invention. First, as shown in FIG. 2, a substrate 101 is provided and a first patterned color layer 110 is formed on the substrate 101. The substrate 101 usually includes a transparent material, such as glass or plastics. Optionally, the substrate 101 may include other elements, such as a black matrix (BM).

The first patterned color layer 110 may be a photoresist material of a certain color and have a pre-determined pattern by some lithographic and exposure procedures. For example, please refer to FIG. 1, a first color photoresist layer 111 is entirely formed on the substrate 101 in advance. Then, please refer to FIG. 2, the first color photoresist layer 111 becomes the first patterned color layer 110 after the lithographic and exposure procedures. The first patterned color layer 110 may have a first color, such as one of red, green or blue.

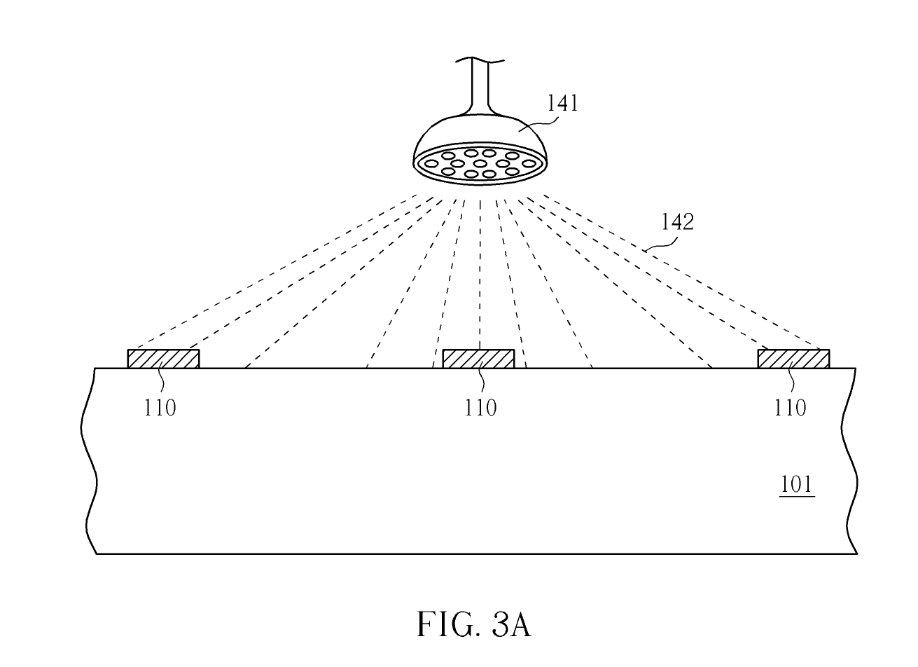

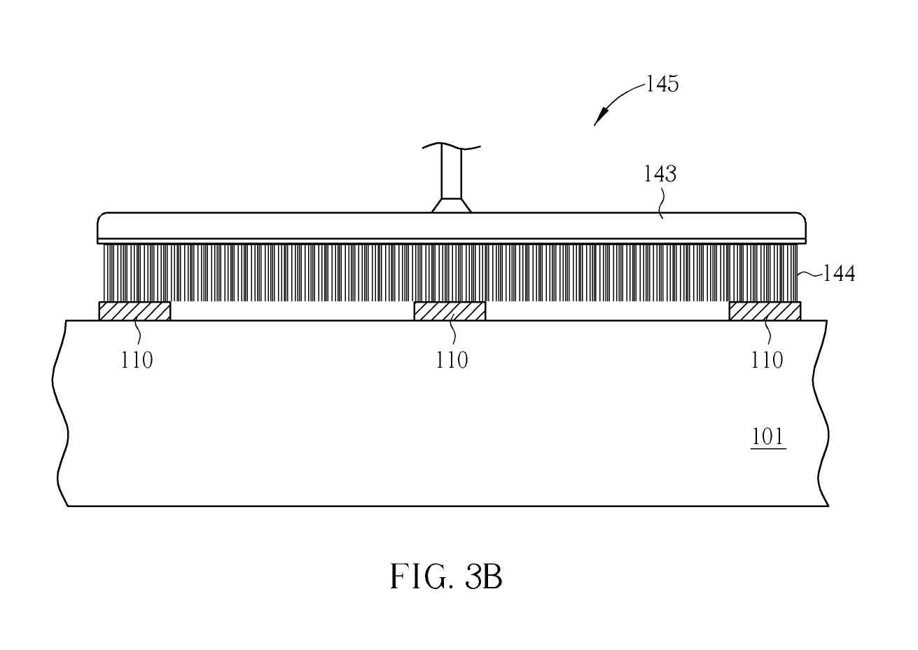

Optionally, please refer to FIG. 3A or FIG. 3B, a washing apparatus 141 or a brushing apparatus 145 may be used to wash the first patterned color layer 110 after exposure and development by the washing apparatus 141 or to brush the first patterned color layer 110 after exposure and development by the brushing apparatus 145. During the washing step or the brushing step, because the detergent 142 and the bristles 144 on the brush 143 directly contact and rub the first patterned color layer 110, the first patterned color layer 110 is required to endure the detergent 142 and the bristles 144 directly contacting and rubbing itself without peeling-off or being damaged.

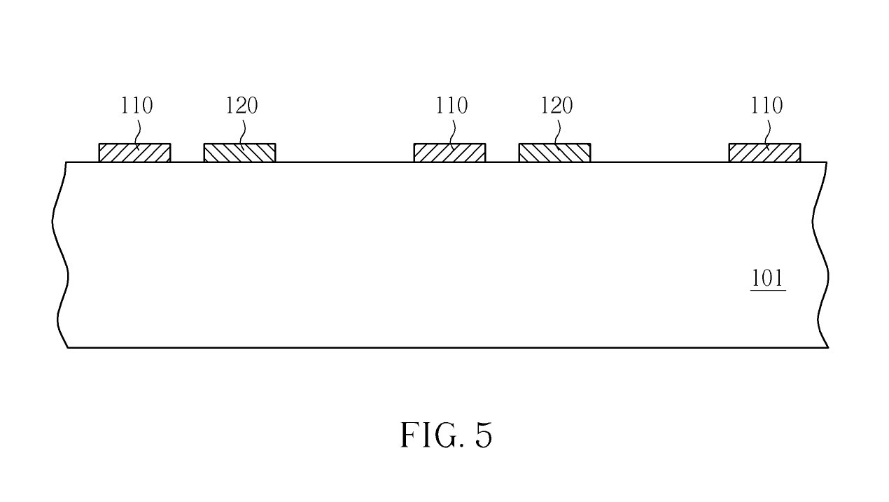

Next, as shown in FIG. 5, a second patterned color layer 120 is formed on the substrate 101 with the first patterned color layer 110. The second patterned color layer 120 has a second color which is different from the first color of the first patterned color layer 110.

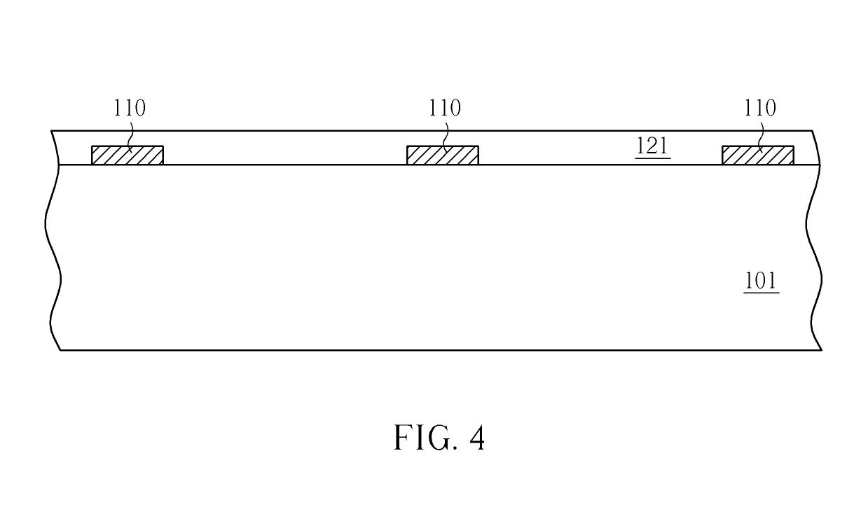

The second patterned color layer 120 may also be a photoresist material of a certain color, such as one of red, green and blue, and have a pre-determined pattern by some lithographic and exposure procedures. For example, please refer to FIG. 4, a second color photoresist layer 121 is entirely formed on the substrate 101 and to cover the previously-formed first patterned color layer 110. Then, please refer to FIG. 5, the second color photoresist layer 121 becomes the second patterned color layer 120 after the lithographic and exposure procedures. Preferably, the second patterned color layer 120 and the first patterned color layer 110 may be arranged in different locations but not limited to this example.

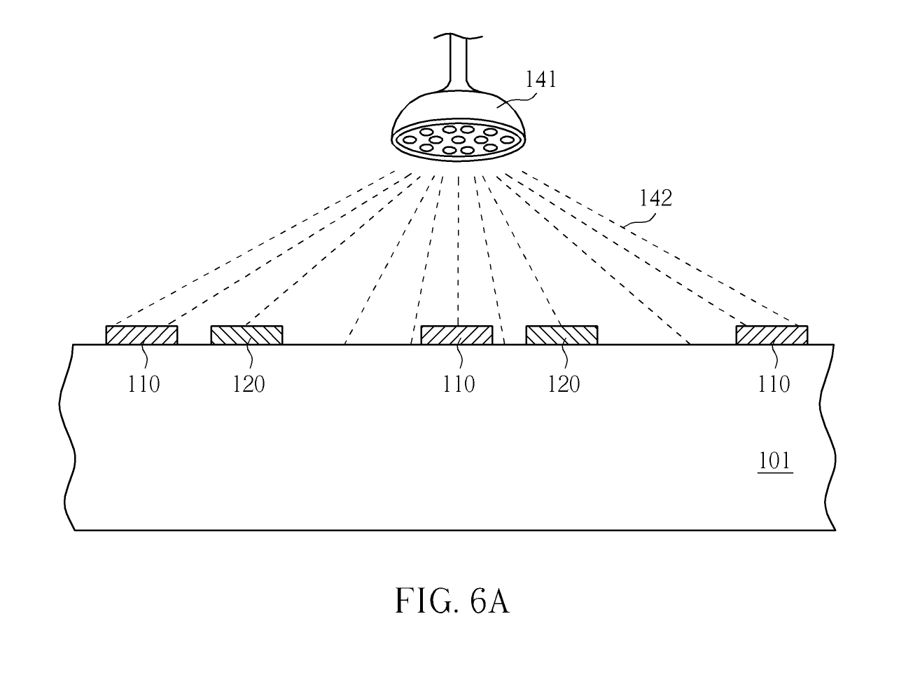

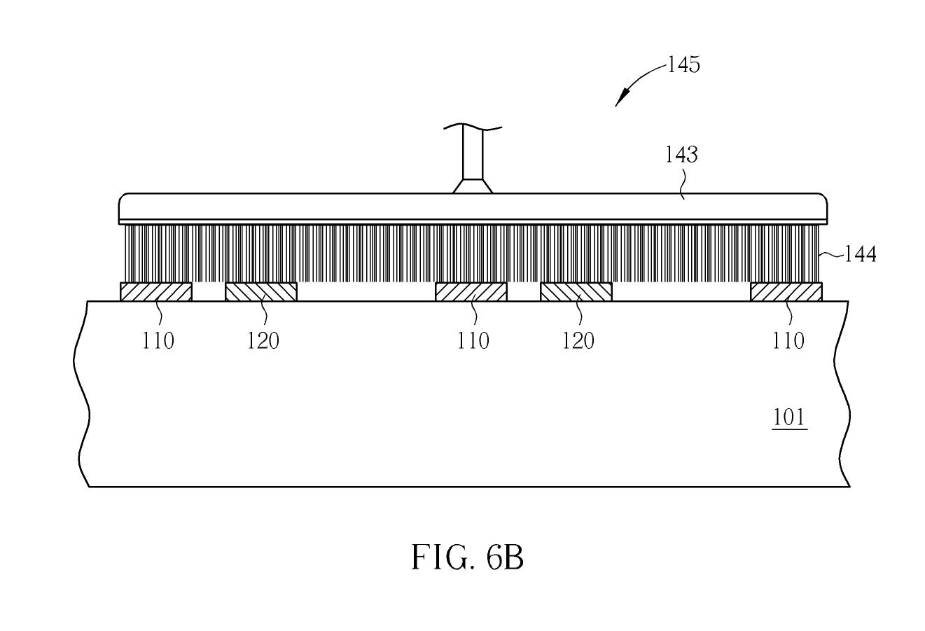

Optionally, please refer to FIG. 6A or FIG. 6B, a washing apparatus 141 or a brushing apparatus 145 may be used to wash the first patterned color layer 110 as well as the second patterned color layer 120 after exposure and development by the washing apparatus 141 or to brush the second patterned color layer 120 after exposure and development by the brushing apparatus 145. During the washing step or the brushing step, because the detergent 142 and the bristles 144 on the brush 143 directly contact and rub the first patterned color layer 110 as well as the second patterned color layer 120, the second patterned color layer 120 is required to endure the detergent 142 and the bristles 144 directly contacting and rubbing itself without peeling-off or being damaged.

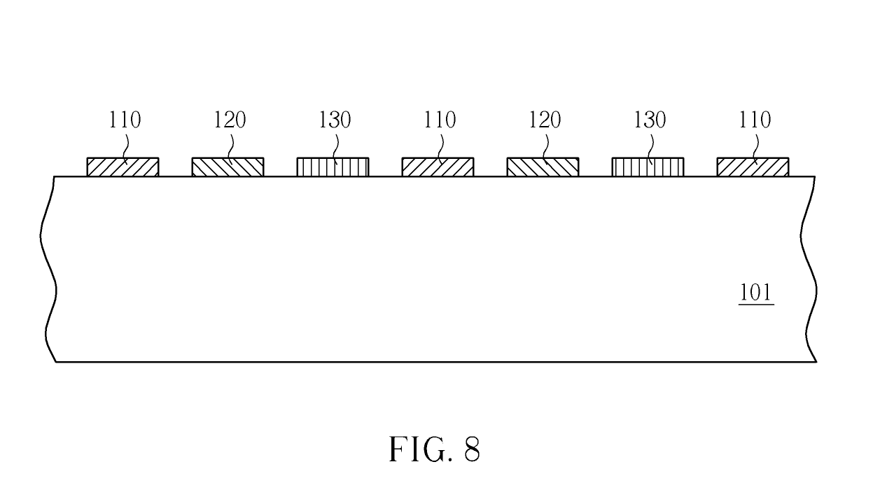

Afterwards, as shown in FIG. 8, a third patterned color layer 130 is formed on the substrate 101 with the first patterned color layer 110 and the second patterned color layer 120. The third patterned color layer 130 has a third color which is different from the first color of the first patterned color layer 110 and the second color of the second patterned color layer 120.

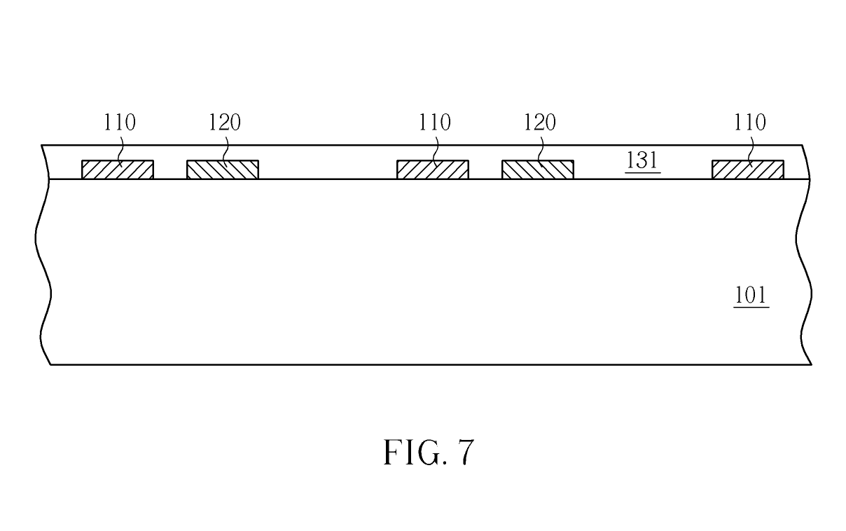

The third patterned color layer 130 may also be a photoresist material of a certain color, such as one of red, green and blue, and have a pre-determined pattern by some lithographic and exposure procedures. For example, please refer to FIG. 7, a third color photoresist layer 131 is entirely formed on the substrate 101 and to cover the previously-formed first patterned color layer 110 and the second patterned color layer 120. Then, please refer to FIG. 8, the third color photoresist layer 131 becomes the third patterned color layer 130 after the lithographic and exposure procedures. Preferably, the third patterned color layer 130, the second patterned color layer 120 and the first patterned color layer 110 may be arranged in different locations but not limited to this example.

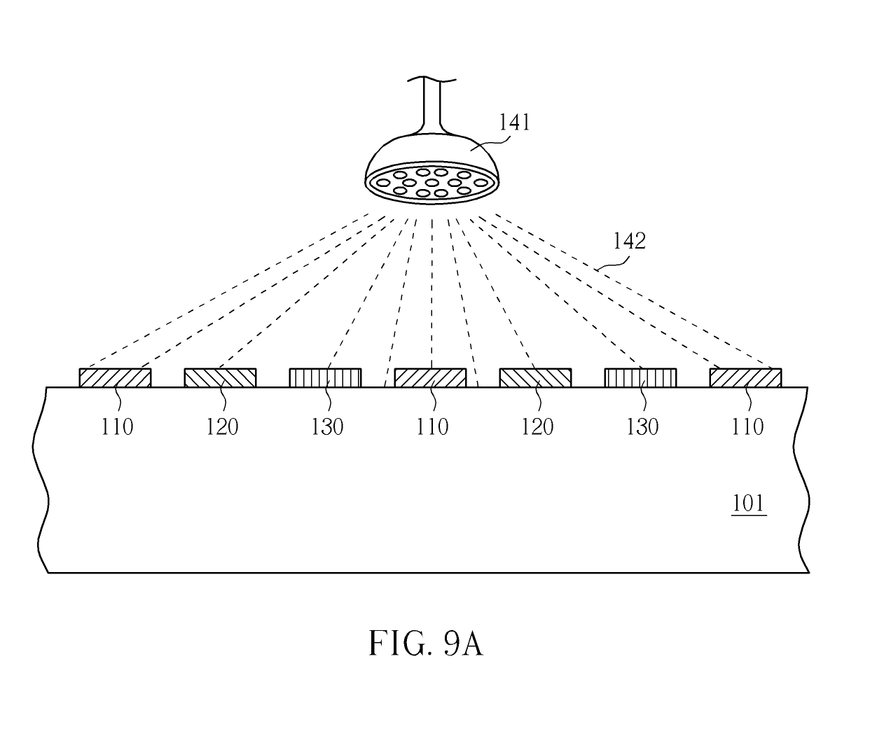

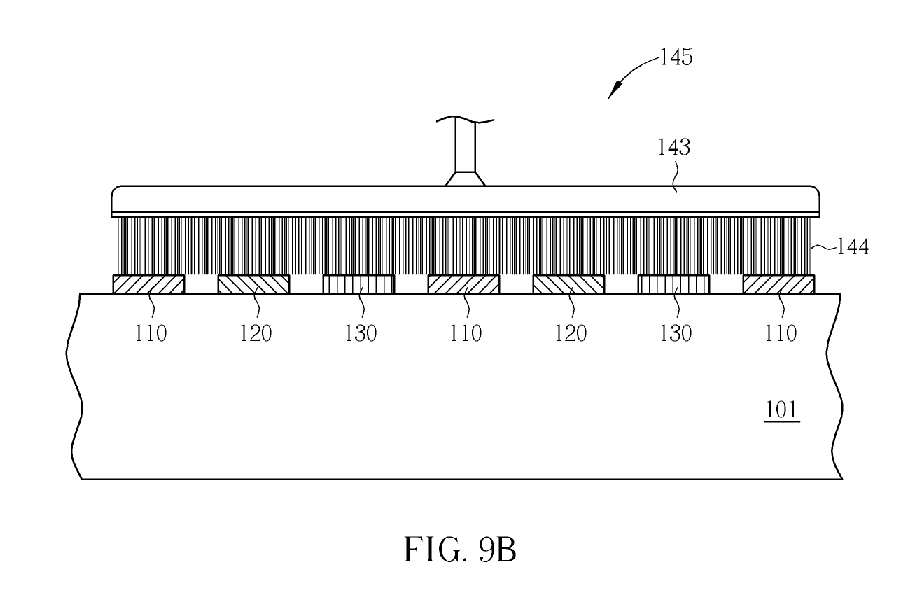

Optionally, please refer to FIG. 9A or FIG. 9B, a washing apparatus 141 or a brushing apparatus 145 may be used to wash the first patterned color layer 110, the second patterned color layer 120 as well as the third patterned color layer 130 after exposure and development by the washing apparatus 141 or to brush the third patterned color layer 130 after exposure and development by the brushing apparatus 145. During the washing step or the brushing step, because the detergent 142 and the bristles 144 on the brush 143 directly contact and rub the first patterned color layer 110, the second patterned color layer 120 as well as the third patterned color layer 130, the third patterned color layer 130 is required to endure the detergent 142 and the bristles 144 directly contacting and rubbing itself without peeling-off or being damaged.

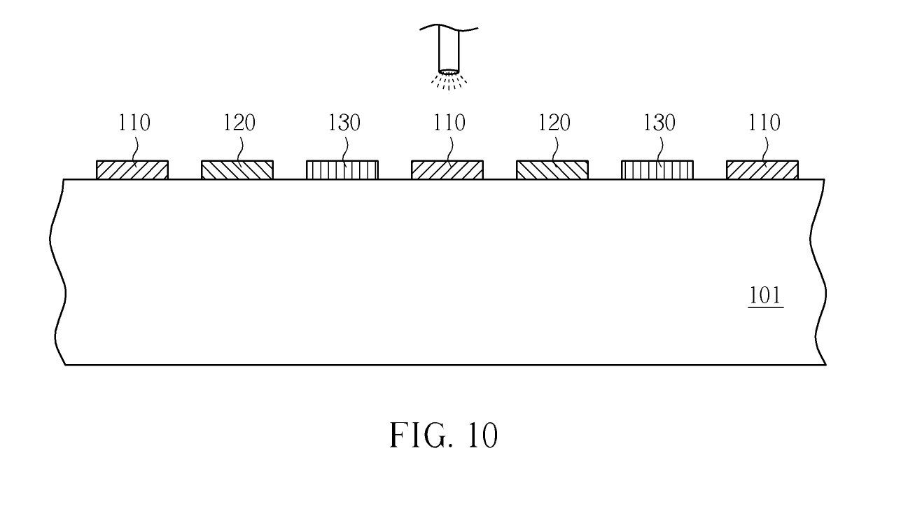

Providing the exposure and development procedures are not used to form the patterned color layers, as shown in FIG. 10, a printing screen process and/or a spraying process may be used to form the third patterned color layer 130, the second patterned color layer 120 and/or the first patterned color layer 110.

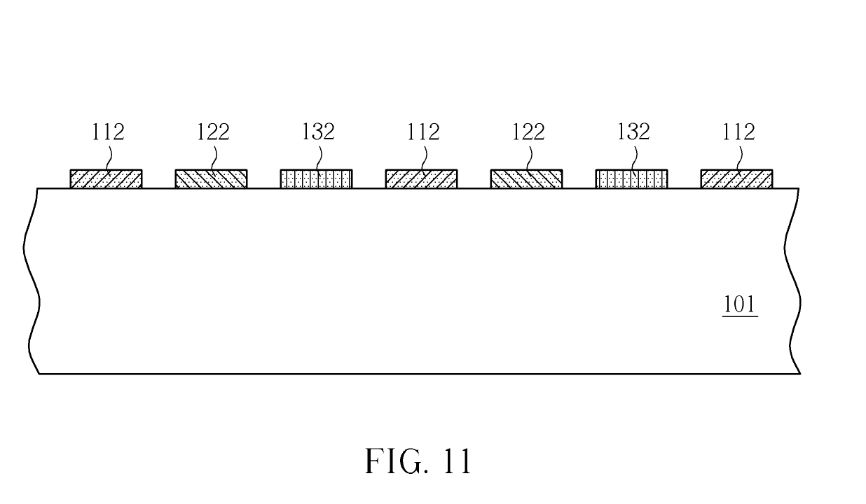

After that, please refer to FIG. 11, a baking step may be carried out to simultaneously turn the first patterned color layer 110, the second patterned color layer 120 and the third patterned color layer 130 into a first pixel color layer 112, a second pixel color layer 122 and a third pixel color layer 132 of the needed multicolor color filters. In other words, all the third patterned color layer 130, the second patterned color layer 120 and the first patterned color layer 110 undergo just only one baking step.

For example, the first patterned color layer 110, the second patterned color layer 120 and the third patterned color layer 130 may be baked together under a temperature of about 200° C.-240° C. for about 20-40 minutes to simultaneously obtain a thermally cured first pixel color layer 112, second pixel color layer 122 and third pixel color layer 132 of the needed multicolor color filters. Preferably, the first patterned color layer 110, the second patterned color layer 120 and the third patterned color layer 130 before the baking step as well as the first pixel color layer 112, second pixel color layer 122 and third pixel color layer 132 after the baking step do not directly contact or overlap one another. The novel method for forming multicolor color filters of the present invention may omit unnecessary baking steps to save a lot of thermal budget. At the same time, the differences or distinctions between the multicolor color filters obtained by the novel method of the present invention and by conventional methods are not substantial as far as the quality or the color is concerned.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming multicolor color filters, comprising:
providing a substrate;
forming a first patterned color layer on said substrate, wherein said first patterned color layer has a first color;
forming a second patterned color layer on said substrate which has said first patterned color layer, wherein said second patterned color layer has a second color;
forming a third patterned color layer on said substrate which simultaneously has said first patterned color layer and said second patterned color layer, wherein said third patterned color layer has a third color and said first color, said second color and said third color being mutually different; and
simultaneously baking said first patterned color layer, said second patterned color layer and said third patterned color layer together to turn said first patterned color layer into a first pixel color layer of said multicolor color filters, to turn said second patterned color layer into a second pixel color layer of said multicolor color filters and to turn said third patterned color layer into a third pixel color layer of said multicolor color filters.

2. The method for forming multicolor color filters of claim 1, wherein forming said first patterned color layer, said second patterned color layer and said third patterned color layer by at least one of a printing screen process and a spraying process.

3. The method for forming multicolor color filters of claim 1, wherein forming said first patterned color layer further comprises:
forming a first color photoresist layer on said substrate; and
exposing and developing said first color photoresist layer to form said first patterned color layer.

4. The method for forming multicolor color filters of claim 3, wherein after forming said first patterned color layer further comprises:
washing said first patterned color layer without substantially damaging said first patterned color layer.

5. The method for forming multicolor color filters of claim 3, wherein after forming said first patterned color layer further comprises:
brushing said first patterned color layer without substantially damaging said first patterned color layer.

6. The method for forming multicolor color filters of claim 1, wherein forming said second patterned color layer further comprises:
forming a second color photoresist layer on said substrate; and
exposing and developing said second color photoresist layer to form said second patterned color layer.

7. The method for forming multicolor color filters of claim 6, wherein after forming said second patterned color layer further comprises:
washing said second patterned color layer without substantially damaging said second patterned color layer.

8. The method for forming multicolor color filters of claim 6, wherein after forming said second patterned color layer further comprises:
brushing said second patterned color layer without substantially damaging said second patterned color layer.

9. The method for forming multicolor color filters of claim 1, wherein forming said third patterned color layer further comprises:
forming a third color photoresist layer on said substrate; and
exposing and developing said third color photoresist layer to form said third patterned color layer.

10. The method for forming multicolor color filters of claim 9, wherein after forming said third patterned color layer further comprises:
washing said third patterned color layer without substantially damaging said third patterned color layer.

11. The method for forming multicolor color filters of claim 9, wherein after forming said third patterned color layer further comprises:
brushing said third patterned color layer without substantially damaging said third patterned color layer.

12. The method for forming multicolor color filters of claim 1, wherein baking said first patterned color layer, said second patterned color layer and said third patterned color layer is carried out for around 20-40 minutes at a temperature around 200° C.-240° C.

13. The method for forming multicolor color filters of claim 1, wherein said first color, said second color and said third color are selected from a group consisting of red, green and blue.

14. The method for forming multicolor color filters of claim 1, wherein said first patterned color layer, said second patterned color layer and said third patterned color layer respectively and independently comprise:
a hydrophobic resin of 15%-25% of a total weight;
an acrylate reactive monomer of 10%-20% of said total weight;
a photo-initiator of 0.5%-3% of said total weight; and
a solvent of 55%-75% of said total weight.

15. The method for forming multicolor color filters of claim 14, wherein at least one of said first patterned color layer, said second patterned color layer and said third patterned color layer further comprises:
an additive up to 3% of said total weight.

16. A color resin composition, comprising:
a hydrophobic resin of 15%-25% of a total weight;
an acrylate reactive monomer of 10%-20% of said total weight;
a photo-initiator of 0.5%-3% of said total weight; and
a solvent of 55%-75% of said total weight.

17. The color resin composition of claim 16, wherein said hydrophobic resin is selected from the following compound:

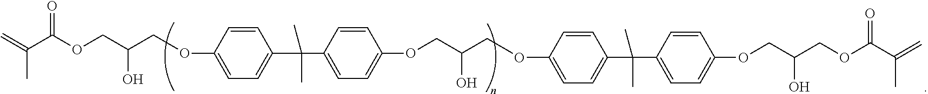

18. The color resin composition of claim 16, wherein said acrylate reactive monomer comprises: 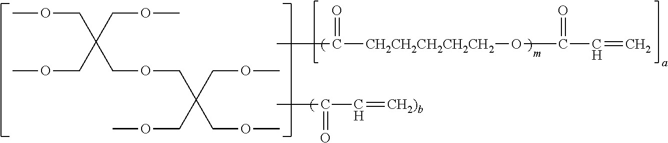
wherein a is 6 and b is 0.

19. The color resin composition of claim 16, further comprising:
an additive up to 3% of said total weight.

20. The color resin composition of claim 19, wherein said additive comprises a thiol compound.

21. The color resin composition of claim 16, wherein said color resin composition being one of red, green and blue.

22. The color resin composition of claim 16, wherein said solvent comprises at least one of ethyl 3-ethoxypropionate, 1-methoxy-2-propyl acetate, 3-methoxybutyl acetate and cyclohexanone.
